(19) United States
(12) Patent Application Publication
(10) Pub. No.: US 2007/0246778 A1
(43) Pub. Date: Oct. 25, 2007

(54) ELECTROSTATIC DISCHARGE PANEL PROTECTION STRUCTURE

(76) Inventors: Meng-Chi Liou, Tao-Yuan Hsien (TW); Chien-Chih Jen, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/379,575

(22) Filed: Apr. 21, 2006

(51) Int. Cl. H01L 23/62

(52) U.S. Cl. 257/362

(57) ABSTRACT

An electrostatic discharge protection structure disposed in a peripheral area of a display panel is electrical connected to a wire of a display area of the display panel and a short ring of the peripheral area. The electrostatic discharge protection structure comprises a first path having a first resistance, and a second path having a second resistance. The first path and the second path are parallel connected between the wire and the short ring, wherein the first resistance is lower than the second resistance.

### BACKGROUND OF THE INVENTION

1. Field of the Invention

The present invention relates to an electrostatic discharge (ESD) protection structure, and more particularly, to an electrostatic discharge protection structure for avoiding a feedback electrostatic discharge.

2. Description of the Prior Art

Please refer to FIG. 1. FIG. 1 is a circuit diagram of an electrostatic discharge protection structure according to the prior art. A peripheral area 100 of an LCD panel has plural electrostatic discharge protection structures 110, 120, and 150. Each electrostatic discharge protection structure 110, 120, 150 is connected to a data line 102, 104, 106 respectively or a scan line (not shown) of a display area of the LCD panel. The structures of the electrostatic discharge protection structures 110, 120, 150 are the same. To take the electrostatic discharge protection structure 120 for example, the electrostatic discharge protection structure 120 has a wire 126 electrically connected to two TFTs (thin film transistor) 122, 124. The TFTs 122, 124 are connected to a short ring 128, and the TFT 122 has a gate 132. The gate 132 shorts to its source (not shown) or drain (not shown). The TFT 124 has a gate 142. The gate 142 shorts to its source (not shown) or drain (not shown).

When the data line 104 of the display area accumulates electrostatic charge, the threshold voltage of the TFT 122 will be reached. The electrostatic charge in the data line 104 passes through the TFT 122 to the short ring 128 by a path 134. When the electrostatic charge passes into the short ring 128, it also passes into the peripheral electrostatic discharge protection structures e.g. electrostatic discharge protection structures 110, and 150 by the paths 118, and 158 respectively. This means the electrostatic charge passes into data lines 102, and 106 from the wires 116, and 156, and the TFTs 114, and 154 respectively. The electrostatic charge spreads in each data line of the display area, so the function of electrostatic discharge protection is achieved. If the electrostatic discharge protection structure 120 has the same voltage difference across the paths, the paths 134, 144 will have the same resistances. The electrostatic charge accumulated in the data line 104 passes into the short ring 128 by the path 134 of the electrostatic discharge protection structure 120. Then, the electrostatic charge is fed back into the data line 104 through the path 144 of the electrostatic discharge protection structure 120. This causes a feedback electrostatic discharge.

Other patents, such as Japan patent JP10-123574, mention forming nonlinear resistance structures on the data line and the scan line to improve the electrostatic discharge. They do not mention any way to solve the problem of the feedback electrostatic discharge, however. Therefore, pursuing a more effective electrostatic discharge protection structure is important.

### SUMMARY OF THE INVENTION

The present invention provides an electrostatic discharge protection structure to solve the above-mentioned problems.

The embodiment of the present invention provides an electrostatic discharge protection structure in a peripheral area of a display panel is electrical connected to a wire of a display area of the display panel and a short ring of the peripheral area. The electrostatic discharge protection structure comprises a first path having a first resistance, and a second path having a second resistance. The second path and the first path are parallel connection between the wire and the short ring, wherein the first resistance is lower than the second resistance.

Another embodiment of the present invention provides an electrostatic discharge protection structure in a peripheral area of a TFT liquid crystal display panel. The electrostatic discharge protection structure is electrical connected to a wire of a display area of the TFT LCD and a short ring of the peripheral area. The electrostatic discharge protection structure comprises a first TFT having a first resistance, and a second TFT having a second resistance. And the second TFT and the first TFT are parallel connection between the wire and the short ring, wherein the first resistance is lower than the second resistance.

Another embodiment of the present invention provides an thin film transistor liquid crystal display panel comprises a display area having a plurality of data lines and a plurality of scan lines, and the data lines and the scan lines are interlocking, and a peripheral area having a short ring and a plurality of electrostatic discharge protection structures. And the electrostatic discharge protection structure is electrical connected to the data line and the short ring and to the scan line and the short ring. And the electrostatic discharge protection structure comprises a first TFT having a first resistance, and a second TFT having a second resistance. And the second TFT and the first TFT are parallel connection, wherein the first resistance is lower than the second resistance.

The resistance of the path passing the electrostatic charge from the data line or the scan line into the short ring is smaller than the resistance of the path passing the electrostatic charge from the short ring into the data line or the scan line in the electrostatic discharge protection structure of the present invention. Thus, the present invention makes the electrostatic charge unable to feed back into the data line or the scan line, avoiding the feedback electrostatic discharge, and thereby increasing the yield of the LCD panel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of an electrostatic discharge protection structure according to the prior art.

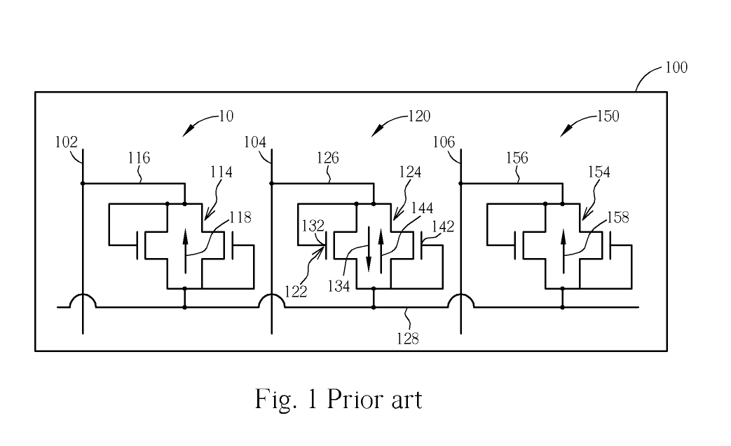

FIG. 2 is a circuit diagram of an electrostatic discharge protection structure according to the present invention.

FIG. 3 is an equivalent circuit diagram of an electrostatic discharge protection structure according to the present invention.

FIG. 4 is a circuit diagram of an electrostatic discharge protection structure according to another embodiment of the present invention.

### DETAILED DESCRIPTION

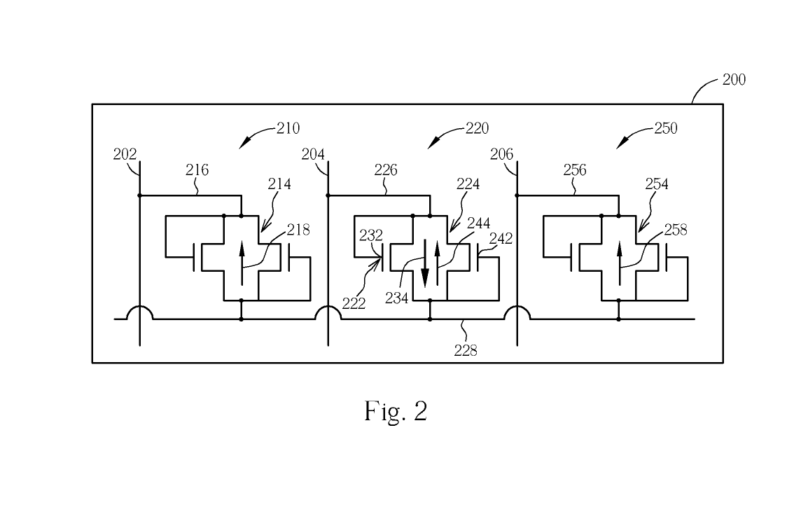

Please refer to FIG. 2. FIG. 2 is a circuit diagram of an electrostatic discharge protection structure according to the present invention. The electrostatic discharge protection structure of the present invention applies to the thin film transistor liquid crystal (TFT LCD) panel or the organic light emitting diodes (OLED) display panel. To take the TFT LCD for example, as FIG. 2 shows, a peripheral area 200 of TFT LCD panel has many electrostatic discharge protection structures 210, 220, and 250. Each electrostatic discharge protection structure 210, 220, 250 is connected to a data line 202, 204, 206 or a scan line (not shown) of a display area of the TFT LCD panel. The structures of the electrostatic discharge protection structures 210, 220, 250 are the same. To take the electrostatic discharge protection structure 220 for example, the electrostatic discharge protection structure 220 has a wire 226 electrically connected to two TFTs (thin film transistor) 222, 224. The TFTs 222, 224 are connected to a short ring 228, and the TFT 222 has a gate 232. The gate 232 shorts to its source (not shown) or drain (not shown). The TFT 224 has a gate 242. The gate 242 shorts to its source (not shown) or drain (not shown). Therefore, the functions of the two TFTs are equal to the functions of two diodes.

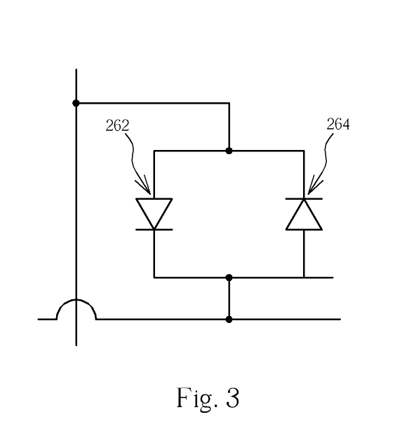

In other words, the TFTs 222, 224 can replace two diodes in other embodiment, as FIG. 3 shows. FIG. 3 is an equivalent circuit diagram of an electrostatic discharge protection structure according to the present invention. The TFTs 222, 224 in FIG. 2 are equal to diodes 422, 424 in FIG. 3.

Please continue to refer to FIG. 2. When each data line of the display area such as the data line 204 of the display area accumulates electrostatic charge, the threshold voltage of the TFT 222 is reached. The electrostatic charge in the data line 204 passes through the TFT 222 to the short ring 228 by a path 234. When the electrostatic charge passes into the short ring 228, the electrostatic charge further passes into the peripheral electrostatic discharge protection structures, e.g. into electrostatic discharge protection structures 210, 250 by the paths 218, 258 respectively. That means the electrostatic charge passes into the data lines 202, 206 from the wires 216, 256 through the TFTs 214, 254. The electrostatic charge spreads in each data line of the display area, so the function of electrostatic discharge protection is achieved.

Please pay attention to that when the electrostatic discharge protection structure applies to TFT LCD panel, the layout of the TFTs 222, 224 can be changed, and the resistance of the TFT 222 is lower than the TFT 224. And the resistance of path 234 is lower than the resistance of path 244. If the value of the transistor channel width/length of the TFT 222 is higher than the value of the transistor channel width/length of the TFT 224, the resistance of the path 234 is lower than the path 244. For example, the length of the TFTs 222, 224 are the same, but the channel width of the TFT 222 is bigger, for example the transistor channel width/length of the TFT 222 is 80/5, and the transistor channel width/length of the TFT 224 is 30/5. Similarly, the channel width of the TFTs 222, 224 are the same, but the channel length of the TFT 222 is lower, for example the transistor channel width/length of the TFT 222 is 50/4, and the transistor channel width/length of the TFT 224 is 50/7. All of them make the resistance of the TFT 222 is lower than the resistance of the TFT 224.

In this embodiment, the electrostatic discharge protection structures 210, 220, 250 are connected to the data lines 202, 204 of the LCD panel. In fact, the electrostatic discharge protection structure can also be connected to the scan line (not shown). The data line and the corresponding scan line can control a pixel unit to turn on or off. In this embodiment, the electrostatic charge from the data line 204 passes into the short ring 228 through the electrostatic discharge protection structure 220, and the whole pixel unit in the data line 204 cannot be electrostatically discharged. Moreover, the electrostatic charge in the short ring 228 cannot be fed back to the data line 204, so the electrostatic charge spreads to several electrostatic discharge protection structures surrounding the electrostatic discharge protection structure 220. Please note that not only the electrostatic discharge protection structures 210, 250 in FIG. 2 can spread the electrostatic charge. If the electrostatic charge can reach the threshold voltage of TFT in the electrostatic discharge protection structure, the electrostatic charge can pass into the data line through the electrostatic discharge protection structure and can be spread.

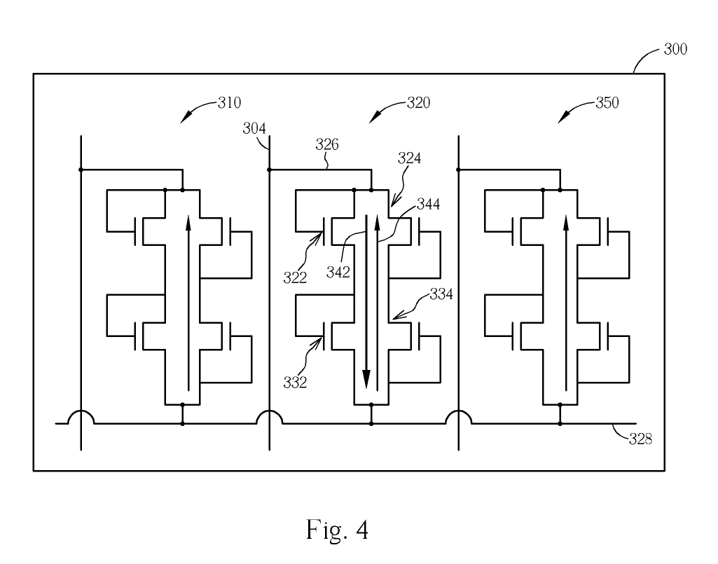

Please refer to FIG. 4. FIG. 4 is a circuit diagram of an electrostatic discharge protection structure according to another embodiment of the present invention. The principles of the embodiment in FIG. 4 and the FIG. 2 are the same. In FIG. 4, however, the electrostatic discharge protection structures 310, 320, 350 in FIG. 4 are made by four TFTs. Take the electrostatic discharge protection structure 320 in FIG. 4 for example. The electrostatic discharge protection structure 320 in the peripheral area 300 of the LCD is connected to a data line 304 by a wire 326. It has four TFTs 322, 324, 332, and 334. The TFTs 322, 332 are connected in series, and the TFTs 324, 334 are connected in series, too. The TFTs 322, 332 and the TFTs 324, 334 are connected in parallel, and then connected to the short ring 328. The resistance of the TFTs 322, 332 is lower than the resistance of the TFTs 324, 334. When the electrostatic charge from the data line 304 passes into the short ring 328 through the path 334 of the electrostatic discharge protection structure 320, the electrostatic charge cannot be fed back into the data line 304 by the path 344 of the electrostatic discharge protection structure 320. The present invention not only utilizes a symmetric amount of TFTs in paths 334, 344, but also utilizes a symmetric amount of TFTs in two paths. The resistance of the path passing the electrostatic charge from the data line into the short ring is lower than the resistance of the path passing the electrostatic charge from the short ring into the data line. This obeys the spirit of the present invention.

Compare with the prior art. The resistance of the path passing the electrostatic charge from the data line or the scan line into the short ring is smaller than the resistance of the path passing the electrostatic charge from the short ring into the data line or the scan line in the electrostatic discharge protection structure of the present invention. The Japan patent JP10-123574 does not have different nonlinear resistances, so it cannot limit the feedback electrostatic discharge. In comparison, the present invention makes the electrostatic charge unable to be fed back into the data line or the scan line, avoiding the feedback electrostatic discharge, and thereby increasing the yield of the LCD. Moreover, the present invention only changes the channel width or length of the TFT, to change the resistance of the TFT. The present invention does not need to change the driver circuits, and does not need to add PEP. So, it can be easily utilized in current display panel manufacturing.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrostatic discharge protection structure in a peripheral area of a display panel, the electrostatic discharge protection structure being electrical connected to a wire of a display area of the display panel and a short ring of the peripheral area, the electrostatic discharge protection structure comprising:
a first path, the first path comprising a first resistance; and
a second path, the second path comprising a second resistance, and the second path and the first path are parallel each other and connection between the wire and the short ring, wherein the first resistance is lower than the second resistance.

2. The electrostatic discharge protection structure of claim 1, wherein the display area comprises at least one scan lines and at least one data lines, wherein the data lines and the scan lines are interlocking.

3. The electrostatic discharge protection structure of claim 2, wherein the wire is electrical connected to the scan line.

4. The electrostatic discharge protection structure of claim 2, wherein the wire is electrical connected to the data line.

5. The electrostatic discharge protection structure of claim 1, wherein both the first path and the second path comprise at least one diode respectively.

6. The electrostatic discharge protection structure of claim 1, wherein the display panel comprises one of a thin film transistor liquid crystal display panel (TFT LCD) and an organic light emitting diodes (OLED) display panel.

7. The electrostatic discharge protection structure of claim 6, wherein both of the first path and the second path comprise at least one TFT.

8. The electrostatic discharge protection structure of claim 7, wherein the TFT has a gate, a source, and a drain, wherein the gate shorts with the source/drain.

9. The electrostatic discharge protection structure of claim 8, wherein the TFT is an equivalent diode.

10. The electrostatic discharge protection structure of claim 8, wherein the TFT of the first path and the TFT of the second path have different value of the transistor channel width divided by the transistor channel length.

11. The electrostatic discharge protection structure of claim 1, wherein the display area has a plurality of electrostatic charges, the electrostatic charges pass into the short ring by the first path, and the electrostatic charges do not go back into the display area by the second path.

12. An electrostatic discharge protection structure in a peripheral area of a TFT liquid crystal display panel, the electrostatic discharge protection structure electrically connected to a wire of a display area of the TFT LCD and a short ring of the peripheral area, the electrostatic discharge protection structure comprising:
a first TFT having a first resistance; and
a second TFT having a second resistance, and the second TFT and the first TFT are parallel connection between the wire and the short ring, wherein the first resistance is lower than the second resistance.

13. The electrostatic discharge protection structure of claim 12, wherein the display area further comprises at least one scan lines and at least one data lines, wherein the data lines and the scan lines are interlocking.

14. The electrostatic discharge protection structure of claim 13, wherein the wire is electrical connected to the scan line.

15. The electrostatic discharge protection structure of claim 13, wherein the wire is electrical connected to the data line.

16. The electrostatic discharge protection structure of claim 12, wherein both of the first TFT and the second TFT have a gate, a source, and a drain, wherein the gate shorts with the source/drain.

17. The electrostatic discharge protection structure of claim 16, wherein both of the first TFT and the second TFT are equivalent diodes.

18. The electrostatic discharge protection structure of claim 12, wherein the first TFT and the second TFT have different value of the transistor channel width divided by the transistor channel length.

19. The electrostatic discharge protection structure of claim 12, wherein the display area has a plurality of electrostatic charges, the electrostatic charges pass into the short ring by the first TFT, and the electrostatic charges do not go back into the display area by the second TFT.
